(19) United States
(12) Patent Application Publication
(10) Pub. No.: US 2025/0199095 A1
(43) Pub. Date: Jun. 19, 2025

(54) MAGNETORESISTIVE SENSOR

(71) Applicant: Infineon Technologies AG, Neubiberg (DE)

(72) Inventors: Bernhard ENDRES, Nabburg (DE); Wolfgang RABERG, Sauerlach (DE); Andreas STRAßER, Regensburg (DE)

(21) Appl. No.: 18/973,916

(22) Filed: Dec. 9, 2024

(30) Foreign Application Priority Data
Dec. 18, 2023 (DE) 102023135655.0

(51) Int. Cl. G01R 33/09

(52) U.S. Cl. CPC G01R 33/098

(57) ABSTRACT

The implementation proposes a magnetoresistive sensor, including at least one xMR sensor element formed from a layer stack, having a magnetically free layer having a magnetically free vortex magnetization, and having at least one reference layer having a reference magnetization in a predetermined direction. Magnetically free layers having a magnetically free vortex magnetization that are arranged along the predetermined direction on opposite sides of the xMR sensor element and laterally adjacent to the xMR sensor element. The adjacent magnetically free layers can act as magnetic flux concentrators for the magnetoresistive sensor element arranged therebetween.

### CROSS-REFERENCE TO RELATED APPLICATION

This application claims priority to Germany Patent Application No. 102023135655.0 filed on Dec. 18, 2023, the content of which is incorporated by reference herein in its entirety.

### TECHNICAL FIELD

The present disclosure relates in general to magnetoresistive sensors and particularly to magnetoresistive sensors having a magnetically free vortex magnetization of the magnetically free layer.

### BACKGROUND

Magnetoresistive effects comprise a number of different physical phenomena, wherein it is common to all of them that an electrical resistance value of a magnetoresistive element can be changed by the behavior of an external magnetic field which acts on the magnetoresistive element. Techniques using magnetoresistive effects are sometimes referred to as “xMR techniques”, where the “x” indicates that a plurality of effects can be addressed in this case, such as the GMR effect (Giant Magnetoresistive effect), the TMR effect (Tunnel Magnetoresistive effect), or the AMR effect (Anisotropic Magnetoresistive effect) to mention only a few examples. xMR effects can be applied in a multiplicity of field-based sensors, for example for measuring rotation, angles, etc. In some applications, in particular in safety-relevant applications, it is necessary for these sensors to operate reliably and at a high level of accuracy.

The alignment of a magnetic reference layer or a reference system of magnetoresistive sensors determines a sensitive axis for the detection of external magnetic fields. For some applications, it is crucial that the magnetoresistive sensor responds only to external magnetic fields along this axis. One problem arises for vortex- or eddy-based magnetoresistive sensors, that is to say sensors having a magnetically free layer with vortex magnetization and having an incorrectly aligned reference system. An x sensor (reference layer with a reference magnetization in the x-direction) then also reacts for example to y fields, since the vortex magnetization of the magnetically free layer is influenced by x and y fields in the same way. A further stabilization of the orientation of the reference layer or of the reference system is not trivial, since the magnetization is also influenced by mechanical stresses (inverse magnetostrictive effect).

There is therefore a need for magnetoresistive vortex- or eddy-based magnetoresistive sensors with improved sensitivity in a predetermined direction.

### SUMMARY

According to a first aspect, a magnetoresistive sensor is proposed. The proposed magnetoresistive sensor includes at least one magnetoresistive sensor element formed from a layer stack. The magnetoresistive sensor element has a magnetically free layer having a magnetically free vortex magnetization and at least one reference layer having a reference magnetization in a predetermined direction. The predetermined direction corresponds to a sensitive axis of the magnetoresistive sensor element (e.g., x or y axis). The magnetoresistive sensor further includes magnetically free layers having a magnetically free vortex magnetization that are arranged along the predetermined direction on opposite sides of the magnetoresistive sensor element and laterally adjacent to the magnetoresistive sensor element.

The use of adjacent magnetically free layers having a magnetically free vortex magnetization next to the magnetoresistive sensor element may increase its sensitivity in the predetermined direction (e.g., x-direction) and decrease its sensitivity in directions perpendicular thereto (e.g., y-direction). In addition, the reference layer or the reference system of the magnetoresistive sensor element can be stabilized by a stray field generated by the adjacent magnetically free layers.

According to some example implementations, the adjacent magnetically free layers have a greater (aspect) ratio of thickness to diameter than the magnetically free layer of the magnetoresistive sensor element.

According to some example implementations, the magnetically free layer of the magnetoresistive sensor element and the adjacent magnetically free layers have identical ratios of thickness to diameter. The thickness and diameter of the magnetically free layer of the magnetoresistive sensor element and of the adjacent magnetically free layers can therefore be different, but in each case have the same ratio to one another.

According to some example implementations, the magnetically free layer of the magnetoresistive sensor element and the adjacent magnetically free layers have identical geometric dimensions. The thickness and diameter of the magnetically free layer of the magnetoresistive sensor element and of the adjacent magnetically free layers can therefore also be identical. As a result, production of the magnetoresistive sensor can be simplified.

According to some example implementations, a lateral distance between the magnetoresistive sensor element and an adjacent magnetically free layer is smaller than twice the diameter of the magnetoresistive sensor element and/or the adjacent magnetically free layer. The distance between the magnetoresistive sensor element and an adjacent magnetically free layer should be so small that the magnetoresistive sensor element can still “see” the stray field of the adjacent magnetically free layers. As a result, the adjacent magnetically free layers can act as magnetic flux concentrators along the predetermined direction.

According to some example implementations, the magnetoresistive sensor element is electrically connected and the adjacent magnetically free layers are electrically open-circuited (not connected), that is to say de-energized. The layer stack of the magnetoresistive sensor element can thus additionally have electrodes, using which the magnetoresistive sensor element is supplied with an electrical supply signal. By contrast, the adjacent magnetically free layers need not be electrically connected to be able to act as magnetic flux concentrators for the magnetoresistive sensor element arranged therebetween.

According to some example implementations, the adjacent magnetically free layers are formed in the same layer of the layer stack as the magnetically free layer of the magnetoresistive sensor element. For example, the adjacent magnetically free layers may be part of adjacent (but de-energized) magnetoresistive sensor elements which are formed in the same layer stack as the magnetoresistive sensor element arranged therebetween. As a result, production of the magnetoresistive sensor can be simplified. In this case, the adjacent magnetoresistive sensor elements are preferably electrically open-circuited (not connected), that is to say de-energized.

According to some example implementations, the adjacent magnetically free layers are formed in layers other than the magnetically free layer of the magnetoresistive sensor element. For example, starting from a common substrate, the adjacent magnetically free layers may be located higher or lower in the vertical direction (z-direction) than the magnetically free layer of the magnetoresistive sensor element. The adjacent magnetically free layers therefore do not require a complete xMR layer stack like the magnetoresistive or xMR sensor element arranged therebetween.

According to some example implementations, the magnetically free layer of the magnetoresistive sensor element and the adjacent magnetically free layers are formed in a circular-disk-shaped manner in each case. Providing the magnetically free layers having a circular-disk-shaped structure may lead to the spontaneous formation of a magnetization pattern having a closed flux (vortex magnetization) in the respective magnetically free layers.

According to some example implementations, the magnetoresistive sensor includes a two-dimensional (2D) matrix arrangement composed of a plurality of (electrically connected) magnetoresistive sensor elements. For this purpose, each of the magnetoresistive sensor elements has laterally adjacent magnetically free layers (not electrically connected) in each case. The magnetoresistive sensor elements and the laterally adjacent magnetically free layers of the matrix arrangement span an x-y plane for example. A lateral distance between a magnetoresistive sensor element and magnetically free layers laterally adjacent thereto is smaller in the predetermined direction (e.g., x-direction) than in a direction perpendicular to the predetermined direction (e.g., y-direction).

According to some example implementations, the at least one magnetoresistive sensor element is configured as a TMR sensor element with a tunnel barrier layer between the magnetically free layer and the reference system.

According to a further aspect, a magnetoresistive sensor is proposed, including a two-dimensional matrix arrangement composed of a plurality of (electrically connected) magnetoresistive sensor elements and magnetically free layers (not electrically connected) laterally adjacent thereto in each case. Each magnetoresistive sensor element has a magnetically free layer having a magnetically free vortex magnetization and a reference layer having a reference magnetization in a predetermined direction. The matrix arrangement has magnetically free layers having a magnetically free vortex magnetization, which are arranged along the predetermined direction on opposite sides of each magnetoresistive sensor element and laterally adjacent to the magnetoresistive sensor element, which magnetically free layers can act as magnetic flux concentrators along the predetermined direction. A lateral distance between a magnetoresistive sensor element and magnetically free layers laterally adjacent thereto is smaller in the predetermined direction than in a direction perpendicular to the predetermined direction. A distance between rows of the two-dimensional matrix arrangement thus differs from a distance between columns of the two-dimensional matrix arrangement.

A magnetically free eddy or vortex magnetization reacts linearly to any external magnetic fields in the plane. The linear range and the sensitivity can be defined using the side ratio of the vortex-magnetized free layer (thickness/diameter). Therefore, an adjacent vortex-magnetized free layer can be used for linear B-field shielding or B-field concentration. In order to reduce the influence of y fields on an x sensor, adjacent vortex-magnetized free layers can be placed next to the magnetoresistive sensor element in the x-direction. This concentrates the x component of the external B field onto the magnetoresistive sensor and simultaneously shields the y component of the external B field.

### BRIEF DESCRIPTION OF THE DRAWINGS

Some examples of apparatuses and/or methods are explained in more detail merely by way of example below with reference to the accompanying FIGS., In the figures:

FIG. 1A shows a schematic illustration of a layer stack of a magnetoresistive sensor element;

FIG. 1B shows a schematic illustration of a magnetoresistive sensor element having a magnetically free layer with vortex magnetization;

FIG. 1C shows an opposite inclination of the reference system of a left and right sensor element in a package;

FIG. 2A shows a schematic plan view of a magnetoresistive sensor according to the present disclosure and external magnetic field in the x-direction;

FIG. 2B shows a schematic plan view of a magnetoresistive sensor according to the present disclosure and external magnetic field in the y-direction;

FIG. 3A shows a drop in the stray field strength in the x-direction;

FIG. 3B shows a drop in the stray field strength in the y-direction;

FIG. 4 shows an increase in the sensitivity of a magnetoresistive sensor in the x-direction and a decrease in the sensitivity of the magnetoresistive sensor in the y-direction;

FIG. 5A shows a schematic illustration of a magnetoresistive sensor having two magnetoresistive sensor elements according to an example implementation of the present disclosure;

FIG. 5B shows a schematic illustration of a magnetoresistive sensor having two magnetoresistive sensor elements according to a further example implementation of the present disclosure;

FIG. 6A shows a schematic illustration of a magnetoresistive sensor having a plurality of magnetoresistive sensor elements in a matrix arrangement according to an example implementation of the present disclosure; and

FIG. 6B shows a schematic illustration of a magnetoresistive sensor having a plurality of magnetoresistive sensor elements in a matrix arrangement according to a further example implementation of the present disclosure.

### DETAILED DESCRIPTION

Some examples are now described in more detail with reference to the accompanying figures. However, further possible examples are not limited to the features of these implementations described in detail. These may include modifications of the features, as well as equivalents and alternatives to the features. In addition, the terminology used herein to describe certain examples should not be restrictive for other possible examples.

Throughout the description of the figures, identical or similar reference signs relate to identical or similar elements or features, each of which may be implemented in an identical or modified form, while providing the same or a similar function. In the figures, the thicknesses of lines, layers and/or areas may also be exaggerated for clarity.

If two elements A and B are combined using an “or”, this should be understood to mean that all possible combinations are disclosed, e.g., only A, only B, and A and B, unless explicitly defined otherwise in the individual case. As alternative wording for the same combinations, it is possible to use “at least one of A and B” or “A and/or B”. This applies equivalently to combinations of more than two elements.

If a singular form, such as “a, an” and “the”, is used, and the use of only a single element is neither explicitly nor implicitly defined as mandatory, other examples may also use a plurality of elements to implement the same function. If a function is described below as being implemented using a plurality of elements, further examples can implement the same function using a single element or a single processing entity. It is also understood that the terms “comprises”, “comprising”, “has” and/or “having” in their use describe the presence of the specified features, integers, steps, operations, processes, elements, components and/or a group thereof, but do not exclude the presence or addition of one or more other features, integers, steps, operations, processes, elements, components, and/or a group thereof.

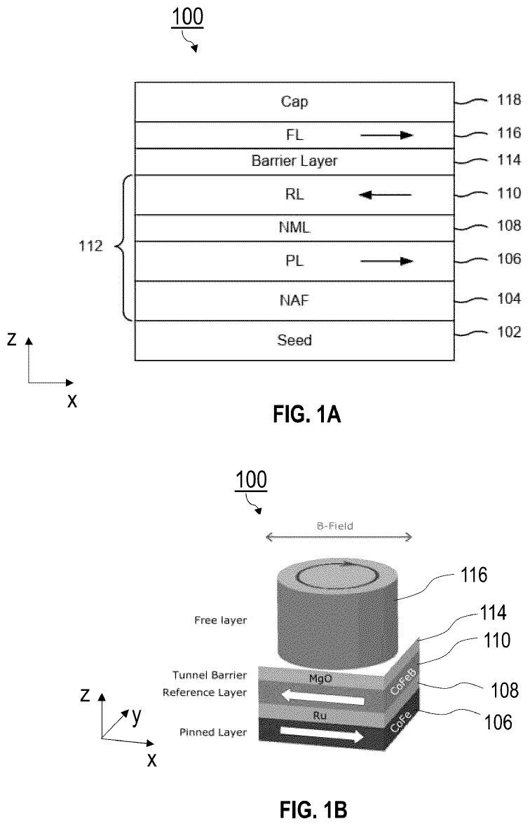

FIG. 1A shows an example of a layer stack of a magnetoresistive sensor element 100 according to one or more implementations.

The magnetoresistive sensor element 100 may for example be a TMR sensor element having a bottom-pinned spin valve (BSV) configuration. GMR sensor elements are likewise possible. In addition, the magnetoresistive sensor element 100 may be arranged on a semiconductor substrate (not shown) of a magnetoresistive sensor. In the description, in a Cartesian coordinate system having coordinate axes x, y and z that are perpendicular to one another in pairs, the layers of the layer stack extend laterally in an xy-plane that is spanned by the x and y axes. Thus, lateral dimensions (e.g., lateral distances, lateral cross-sectional areas, lateral areas, lateral extents, lateral displacements, etc.) may relate to dimensions in the xy-plane and vertical dimensions may relate to dimensions in the z-direction, perpendicular to the xy-plane. Thus, for example, the vertical extent of a layer in the z-direction can be referred to as the layer thickness.

The layer stack of the magnetoresistive sensor element 100 comprises at least one reference layer with a reference magnetization (e.g., a reference direction in the case of GMR or TMR technology). The reference magnetization is a magnetization direction that provides a sensor direction that corresponds to a sensor axis of the magnetoresistive sensor element 100. The reference layer and consequently the reference magnetization define a sensor plane. The sensor plane may be defined by the xy-plane for example. Thus, the x-direction and the y-direction can be referred to as “in-plane” in relation to the sensor plane and the z-direction can be referred to as “out-of-plane” in relation to the sensor plane.

Accordingly, in the case of a GMR sensor element or a TMR sensor element, the resistance of the magnetoresistive sensor element 100 is at a minimum when the magnetically free magnetization of a magnetic free layer points in exactly the same direction as the reference magnetization (e.g., the reference direction) and the resistance of the magnetoresistive sensor element 100 is at a maximum when the magnetically free magnetization of the magnetic free layer points in exactly the opposite direction to the reference magnetization. The orientation of the magnetically free magnetization of the magnetically free layer is variable in the presence of an external magnetic field. Thus, the resistance of the magnetoresistive sensor element 100 may vary based on the influence of the external magnetic field on the magnetically free magnetization of the magnet-free layer.

From bottom to top, the magnetoresistive sensor element 100 may comprise an optional seed layer 102 that can be used to influence and/or optimize stack growth. In some implementations, the seed layer 102 may consist of copper, tantalum, ruthenium or a combination thereof. In the example shown, a natural antiferromagnetic (NAF) layer 104 is formed or arranged in some other way on the seed layer 102. The NAF layer 104 may consist of platinum-manganese (PtMn), iridium-manganese (IrMn), nickel-manganese (NiMn) or the like. The layer thickness of the NAF may for example be in the range from 5 (nanometer) nm to 50 nm.

Moreover, a pinned layer (PL) 106 may be formed or otherwise arranged on the NAF layer 104. The pinned layer 106 may consist of a ferromagnetic material such as cobalt-iron (CoFe) or cobalt-iron-boron (CoFeB). The contact between the NAF layer 104 and the pinned layer 106 may bring about an effect known as the exchange bias effect and cause the magnetization of the pinned layer 106 to align in a preferred direction (e.g., in the x-direction, as shown). The magnetization of the pinned layer 106 may be referred to as pinned magnetization. The pinned layer 106 may have a linear magnetization pattern in the xy-plane (e.g., a homogeneous alignment in one direction) that is permanently fixed.

The magnetoresistive sensor element 100 also comprises a nonmagnetic layer (NML) that is referred to as an intermediate coupling layer 108. In one possible implementation, the intermediate coupling layer 108 may for example comprise ruthenium, iridium, copper, copper alloys or similar materials. Other materials (e.g., paramagnets) are likewise possible. A magnetic (e.g., ferromagnetic) reference layer (RL) 110 can be formed or otherwise arranged on the intermediate coupling layer 108. The thickness of the pinned layer 106 and the magnetic reference layer 110 may be in the range from 1 nm to 10 nm.

Accordingly, the intermediate coupling layer 108 can be arranged between the pinned layer 106 and the magnetic reference layer 110 to spatially separate the pinned layer 106 and the magnetic reference layer 110 in the vertical direction. Moreover, the intermediate coupling layer 108 may provide interlayer exchange coupling (e.g., antiferromagnetic Ruderman-Kittel-Kasuya-Yosida (RKKY) coupling) between the pinned layer 106 and the magnetic reference layer 110 to form an artificial antiferromagnet. As a result, a magnetization of the magnetic reference layer 110 may align and be maintained in a direction that is antiparallel or opposite to the magnetization of the pinned layer 106 (e.g., in the x-direction, as shown). The magnetization of the magnetic reference layer 110 may be referred to as reference magnetization.

Since the NAF layer 104 is configured such that it aligns and fixes the magnetization of the pinned layer 106 in a particular direction, and the intermediate coupling layer 108 is configured such that it aligns and fixes the magnetization of the magnetic reference layer 110 in an opposite direction, it can be the that that the NAF layer 104 is configured such that it maintains the magnetization of the pinned layer 106 (e.g., a fixed magnetization) in a first magnetic alignment and maintains the magnetization of the magnetic reference layer 110 (e.g., a fixed reference magnetization) in a second magnetic alignment. The magnetic reference layer 110 may have a linear magnetization pattern in a particular direction in the xy-plane when the pinned layer 106 has a linear magnetization pattern in an antiparallel direction. Thus, the NAF layer 104, the pinned layer 106, the intermediate coupling layer 108, and the magnetic reference layer 110 form a magnetic reference layer system 112 of the magnetoresistive sensor element 100.

The magnetoresistive sensor element 100 additionally comprises a barrier layer 114 (e.g., a tunnel barrier) that is arranged vertically between the reference layer system 112 and a magnet-free layer 116. The barrier layer 114 can for example be formed or otherwise arranged on the magnetic reference layer 110 of the reference layer system 112 and the magnetically free layer 116 can be formed or otherwise arranged on the barrier layer 114.

The barrier layer 114 may consist of a non-magnetic material. In some implementations, the barrier layer 114 may be an electrically insulating tunnel barrier layer. For example, the barrier layer 114 may be a tunnel barrier layer that is used to generate a TMR effect. The barrier layer 114 may consist of magnesium oxide (MgO) or another material having similar properties.

The material of the magnetically free layer 116 may be an alloy of a ferromagnetic material, such as CoFe, CoFeB or NiFe. The magnetically free layer 116 has a magnetically free magnetization which is variable in the presence of an external magnetic field. Therefore, the magnetically free layer 116 can be referred to as a sensor layer since changes in the magnetically free magnetization are used to determine a measurement variable. Moreover, in a ground state, the magnetically free magnetization has a standard magnetic alignment (such as, for example, a vortex magnetization). The ground state is a state in which the influence of the external magnetic field on the magnetically free layer 116 is not present or is negligibly small. In some implementations, the magnetoresistive sensor element 100 may comprise a magnetically free system that includes a plurality of layers (e.g., two or more magnetically free layers) which act in combination as a magnetically free layer. In this case, the magnetically free layers of the magnetically free system are magnetically coupled to one another. The magnetically free system can therefore function as a magnetically free layer, but can also consist of a plurality of layers. The magnetically free system has a magnetically free magnetization, wherein the magnetically free magnetization is variable in the presence of the external magnetic field.

A cover layer 118, for example made of tantalum (Ta), tantalum nitride (TaN), ruthenium (Ru), titanium (Ti), titanium nitride (TiN), platinum (Pt) or the like may be formed or otherwise arranged on the magnetically free layer 116 to form an upper layer of the magnetoresistive sensor element 100.

The seed layer 102 may serve as a bottom electrode or make electrical contact with a bottom electrode (not shown) of the magnetoresistive sensor element 100. The cover layer 118 may make electrical contact with a top electrode (not shown) of the magnetoresistive sensor element 100. The barrier layer 114 may be configured such that electrons can tunnel between the reference layer system 112 and the magnetically free layer 116 when a bias voltage is applied to the electrodes of the magnetoresistive sensor element 100 (not shown) to generate a magnetoresistance effect (e.g., a TMR effect).

As mentioned above, FIG. 1A is used merely as an example of a magnetoresistive sensor element. Other examples may differ from the description in FIG. 1. The number and arrangement of the components shown in FIG. 1A is an example. In practice, the magnetoresistive sensor element 100 may include additional elements or layers, fewer elements, other elements or elements arranged differently than those shown in FIG. 1A.

FIG. 1B shows a simplified perspective illustration of the magnetoresistive sensor element 100, in which the magnetically free layer 116 is formed in a circular-disk-shaped manner in order to form a vortex magnetization spontaneously (that is to say automatically) in the ground state. The circular-disk-shaped magnetically free layer 116 has a diameter D which may for example be in a range from several hundred nm to 10 micrometer (μm). The magnetically free layer 116 further has a thickness T in the range of e.g., one nm to 100 or 200 nm. Providing a layer having this structure may result in spontaneous formation of a magnetization pattern having closed flux in the magnetically free layer 116. The occurrence of such a field can also be called a vortex state or a vortex configuration. In other words, the vortex state can be obtained by selecting the disk thickness T in the range of, for example, 10 nm up to 200 nm and the disk diameter D between 100 nm and 3 μm. The vortex spin valve structure is not limited to the TMR effect; for example, it can also be realized using a GMR structure.

In the case of a differential magnetoresistive magnetic field sensor for measuring differential external magnetic fields in the x-direction, it is possible for example to provide two magnetoresistive sensor elements 100 which are adjacent in the x-direction and ideally each have a reference layer 110 that is magnetized in the positive or negative x-direction. The alignment of the magnetic reference layer 110 or the reference system 112 of magnetoresistive sensors determines the sensitive axis for the detection of external magnetic fields. For some applications, it is crucial that the magnetoresistive sensor responds only to external magnetic fields along this axis. A differential magnetic field sensor for measuring differential external magnetic fields in the x-direction should for example only respond to external magnetic fields along the x-axis. A problem occurs for vortex- or eddy-based magnetoresistive sensors having a reference layer 110 that is not ideally aligned or a reference system 112 that is not ideally aligned.

FIG. 1C schematically shows a differential magnetoresistive magnetic field sensor 150 for measuring differential external magnetic fields in the x-direction. Both magnetoresistive sensor elements 100A, 100B of the differential magnetic field sensor 150 each have a reference system that is not ideally aligned. While in the left magnetoresistive sensor element 100A, the reference magnetization has a desired component in the positive x-direction and an undesired component in the positive y-direction, in the right magnetoresistive sensor element 100B, reference magnetization has a desired component in the positive x-direction and an undesired component in the negative y-direction. Thus, the vortex- or eddy-based magnetic field sensor 150 also reacts to y fields for example, since the vortex magnetization of the respective magnetically free layer 116 of the sensor elements 100A, 100B is influenced in the same way by x and y fields. Stabilization of the orientation of the reference system 112 is not trivial, since the magnetization is also influenced by mechanical stresses (inverse magnetostrictive effect).

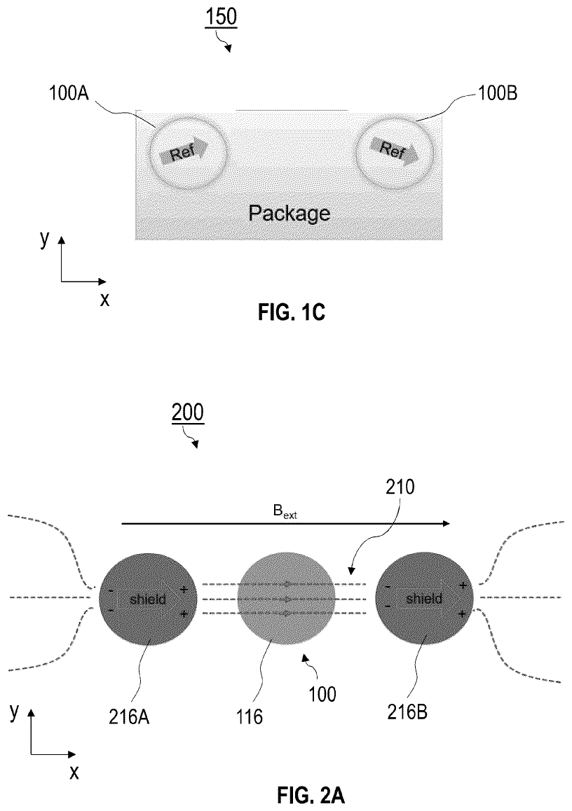

FIG. 2A shows a schematic plan view of a magnetoresistive sensor 200 according to an example implementation.

The magnetoresistive sensor 200 comprises at least one magnetoresistive sensor element 100 formed from a layer stack (see FIGS. 1A, 1B). The magnetoresistive sensor element 100 has a magnetically free layer 116 having a magnetically free vortex magnetization and at least one reference layer 110 having a linear reference magnetization (mainly) in a predetermined direction (here: x-direction). As mentioned above, an actual direction of the reference magnetization may deviate from the ideal direction (here: x-direction) (for example influenced by mechanical stresses). In order to stabilize the orientation of the reference layer 110 or the reference system 112 of the magnetoresistive sensor element 100, the magnetoresistive sensor 200 has (additional) magnetically free layers 216A, 216B, each having a magnetically free vortex magnetization, arranged along the predetermined direction (desired sensitivity direction) on opposite sides of the magnetoresistive sensor element 100 and laterally adjacent to the magnetoresistive sensor element 100.

Due to the magnetically free layers 216A, 216B on the left and right next to the magnetoresistive sensor element 100, the measurement sensitivity thereof can be increased in the x-direction and reduced in the y-direction. In addition, the reference layer 110 or the reference system 112 of the magnetoresistive sensor element 100 is stabilized by the stray field 210 generated by the magnetically free layers 216A, 216B. The alignment of the magnetically free magnetization of the respective magnetically free layers 216A (left), 116 (center), 216B (right) follows the external magnetic field Bₑₓₜ. Thus, a linear stray field 210 is formed in the x-direction between the adjacent magnetically free layers 216A (left) and 216B (right), which increases the sensitivity of the magnetoresistive sensor element 100 in the x-direction.

The stray field 210 generated by the adjacent magnetically free layers 216A, 216B in the case of an external magnetic field in the y-direction is illustrated in FIG. 2B. The stray field 210 runs counter to the external magnetic field Bₑₓₜ in the region of the magnetoresistive sensor element 100 between the adjacent magnetically free layers 216A, 216B, so that the sensitivity of the magnetoresistive sensor element 100 is reduced in the y-direction.

According to example implementations of the present disclosure, both the magnetically free layer 116 of the magnetoresistive sensor element 100 and the adjacent magnetically free layers 216A, 216B (within the scope of manufacturing tolerances) have identical ratios of thickness (T) to diameter (D). This makes it possible to cause the magnetically free layer 116 of the magnetoresistive sensor element 100 and the adjacent magnetically free layers 216A, 216B to behave virtually identically in response to an external magnetic field Bₑₓₜ and their respective magnetically free magnetization to be similarly influenced by the external magnetic field Bₑₓₜ. The magnetically free layer 116 of the magnetoresistive sensor element 100 and the adjacent magnetically free layers 216A, 216B may to this end have identical geometric dimensions (within the scope of manufacturing tolerances) in the x-, y-, and z-directions.

According to example implementations of the present disclosure, the magnetically free layers 216A, 216B are each equidistant from a geometric center of the magnetically free layer 116 of the magnetoresistive sensor element 100. That is to say, the magnetically free layers 216A, 216B are arranged along the x-axis (or y-axis) symmetrically with respect to the magnetoresistive sensor element 100 through which an axis of symmetry 220 runs in the y-direction (or x-direction). Here, a lateral distance (e.g., in the x-direction) between the magnetoresistive sensor element 100 and an adjacent magnetically free layer 216A, 216B is smaller than twice the diameter (2*D) of the magnetoresistive sensor element 100 or the adjacent magnetically free layer 216A, 216B. Here, the lateral distance can be measured in the predetermined direction, for example from the center of the magnetically free layer 116 of the magnetoresistive sensor element 100 to the center of the respective adjacent magnetically free layer 216A, 216B, such that the lateral distance between the magnetoresistive sensor element 100 and an adjacent magnetically free layer 216A, 216B may be between D and 2D. A distance of D would mean that magnetoresistive sensor element 100 and adjacent magnetically free layer 216A, 216B are located directly next to one another (without intermediate space). A distance of 2D would mean an intermediate space of D between magnetoresistive sensor element 100 and adjacent magnetically free layer 216A, 216B.

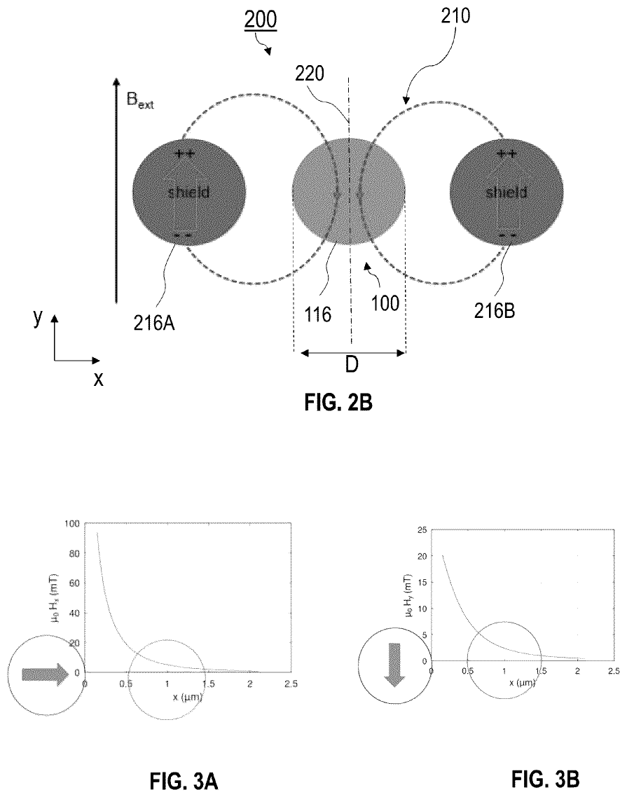

A decay of the stray field 210 in the x-direction for an adjacent magnetically free layer 216A, 216B that is x-magnetized by an external magnetic field and having a diameter D=1 μm and a thickness T=80 nm is shown in FIG. 3A. A decay of the stray field 210 in the x-direction for an adjacent magnetically free layer 216A, 216B that is y-magnetized by an external magnetic field and having a diameter D=1 μm and a thickness T=80 nm is shown in FIG. 3B. If the influence of the stray field 210 on the magnetoresistive sensor element 100 should be as large as possible, a small lateral distance between the magnetoresistive sensor element 100 and an adjacent magnetically free layer 216A, 216B is advantageous.

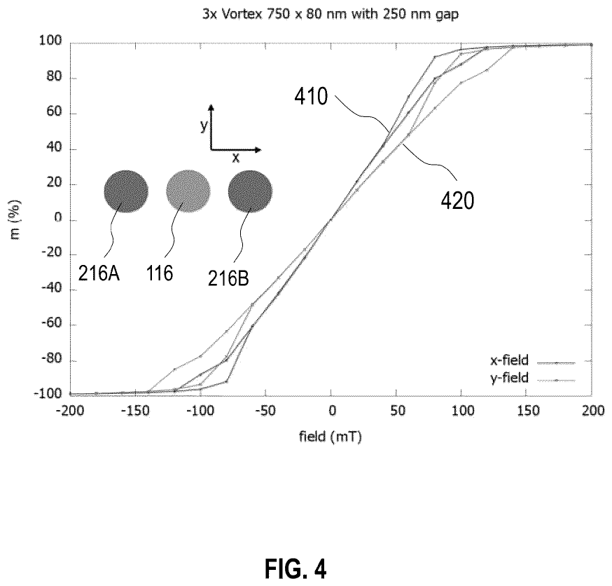

FIG. 4 shows the influence of the proposed concept with the adjacent magnetically free layers 216A, 216B (as magnetic flux concentrators) on the sensitivity of a vortex-magnetized magnetoresistive sensor element 100. By arranging the adjacent magnetically free layers 216A, 216B to the left and right next to the magnetoresistive sensor element 100, its sensitivity in the x-direction can be increased from 0.9%/mT to 1.10%/mT (curve 410) and in the y-direction can be reduced from 0.9%/mT to 0.85%/mT (curve 420). The simulation shown in FIG. 4 is based on identically dimensioned magnetically free layers 116, 216A, 216B with a respective diameter D=750 nm, a thickness T=80 nm and an intermediate space of 250 nm.

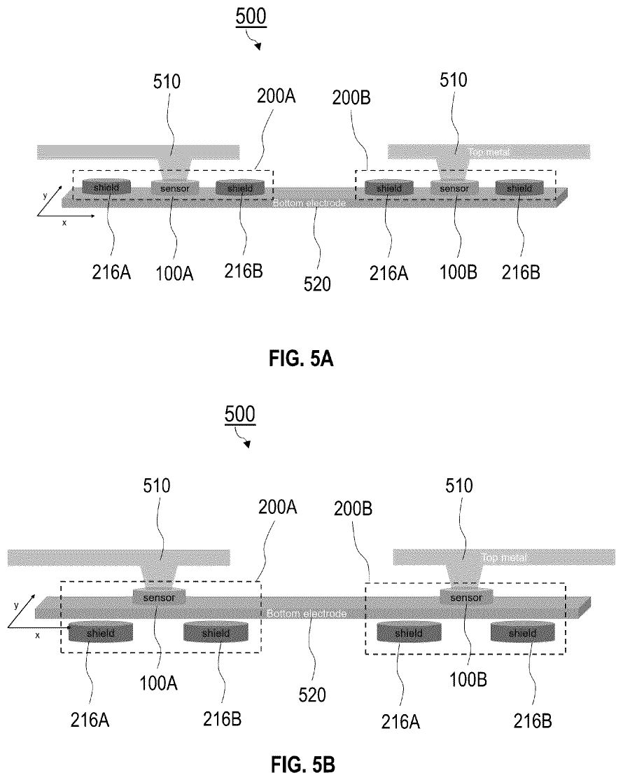

FIG. 5A schematically shows a sensor arrangement 500, in which two magnetoresistive sensors 200A and 200B are arranged to be laterally adjacent in the x-direction on a common substrate. The two magnetoresistive sensors 200A and 200B may for example form a differential magnetic field sensor 500.

A left magnetoresistive sensor 200A of the sensor arrangement 500 comprises at least one xMR sensor element 100A that is formed from a layer stack (see FIGS. 1A, 1B). The xMR sensor element 100A has a magnetically free layer 116 (not shown) having a magnetically free vortex magnetization, and at least one reference layer 110 (not shown) having a linear reference magnetization in a predetermined sensitivity direction (e.g., x-direction). In order to stabilize the orientation of the reference layer 110 of the xMR sensor element 100A, the magnetoresistive sensor 200A has magnetically free layers 216A, 216B, each having a magnetically free vortex magnetization, arranged along the predetermined sensitivity direction on opposite sides of the xMR sensor element 100A and laterally adjacent to the xMR sensor element 100A. The xMR sensor element 100A is therefore embedded along the predetermined sensitivity direction between the adjacent magnetically free layers 216A, 216B.

A right magnetoresistive sensor 200B of the sensor arrangement 500 comprises at least one xMR sensor element 100B that is formed from a layer stack (see FIGS. 1A, 1B). The xMR sensor element 100B has a magnetically free layer 116 (not shown) having a magnetically free vortex magnetization, and at least one reference layer 110 (not shown) having a linear reference magnetization in the predetermined sensitivity direction (e.g., x-direction). In order to stabilize the orientation of the reference layer 110 of the xMR sensor element 100B, the magnetoresistive sensor 200B has magnetically free layers 216A, 216B, each having a magnetically free vortex magnetization, arranged along the predetermined sensitivity direction on opposite sides of the xMR sensor element 100B and laterally adjacent to the xMR sensor element 100B. The xMR sensor element 100B is therefore likewise embedded along the predetermined sensitivity direction between adjacent magnetically free layers 216A, 216B.

In the sensor arrangement 500 of FIG. 5A, the adjacent magnetically free layers 216A, 216B may be formed in the same layer of the layer stack as the magnetically free layer 116 of the respective xMR sensor element 100A, 110B. For example, the adjacent magnetically free layers 216A, 216B may be part of adjacent xMR sensor elements that are not electrically connected (that is to say de-energized). At least, the adjacent magnetically free layers 216A, 216B may be formed in layers on the same side of (e.g., above) the electrode 520 as the magnetically free layer 116 of the respective xMR sensor element 100A, 110B.

A distance between the right magnetically free layer 216B of the left sensor 200A and the left magnetically free layer 216A of the right sensor 200B is greater than a distance between the xMR sensor element 100A and its left and right adjacent magnetically free layers 216A, 216B or than a distance between the xMR sensor element 100B and its left and right adjacent magnetically free layers 216A, 216B.

A bottom electrode 520 forms a substrate for the xMR sensor elements 100A, 100B and the respective left and right adjacent magnetically free layers 216A, 216B. While the xMR sensor elements 100A, 100B are additionally electrically connected to a respective top electrode layer 510 and thus via the top and bottom electrodes 510, 520 in a CPP configuration (CPP: Current Perpendicular to Plane), the respective adjacent magnetically free layers 216A, 216B are at least not connected to the respective top electrode 510. The magnetically free layers 216A, 216B are therefore not electrically connected and are thus de-energized (no current flows through them). Rather, they serve as magnetic flux concentrators along the predetermined sensitivity direction.

FIG. 5B shows an alternative implementation of the sensor arrangement 500, in which the adjacent magnetically free layers 216A, 216B are formed in layers other than the magnetically free layer 116 of the respective xMR sensor element 100A, 110B. In FIG. 5B, the adjacent magnetically free layers 216A, 216B are formed in layers on an opposite side of (e.g., below) the electrode 520 to the magnetically free layer 116 of the respective xMR sensor element 100A, 110B. Here too, the adjacent magnetically free layers 216A, 216B are not (electrically) connected. They are used as magnetic flux concentrators along the predetermined sensitivity direction.

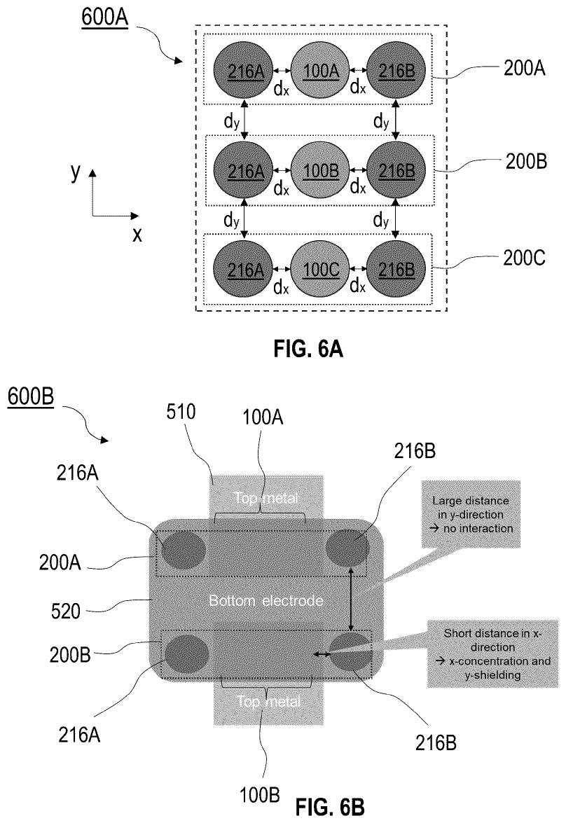

FIG. 6A schematically shows a sensor arrangement 600A according to a further example implementation.

The sensor arrangement 600A comprises a 2-dimensional matrix arrangement composed of a plurality of xMR sensor elements 100A, 100B, 100C arranged in the y-direction. Magnetically free layers 216A, 216B (e.g., sets of magnetically free layers 216A, 216B) are arranged adjacent to each of the xMR sensor elements 100A, 100B, 100C on the left and right in the x-direction. FIG. 6A shows a matrix with three rows and three columns by way of example. Each row forms a magnetoresistive (sub) sensor 200 having an xMR sensor element 100 that is embedded in the x-direction between adjacent magnetically free layers 216A, 216B. A first row of the matrix arrangement forms a first (sub) sensor 200A having a first xMR sensor element 100A which is embedded in the x-direction between adjacent magnetically free layers 216A, 216B. A second row forms a second (sub) sensor 200B having a second xMR sensor element 100B which is embedded in the x-direction between adjacent magnetically free layers 216A, 216B. A third row forms a third (sub) sensor 200C having a third xMR sensor element 100C which is embedded in the x-direction between adjacent magnetically free layers 216A, 216B. A first column of the matrix arrangement is formed by the three magnetically free layers 216A of the (sub) sensors 200A, 200B and 200C, which are situated one below the other in the y-direction. A second column is formed by the three xMR sensor elements 100A, 100B and 100C of the (sub) sensors 200A, 200B and 200C, which are situated one below the other in the y-direction. A third column is formed by the three magnetically free layers 216B of the (sub) sensors 200A, 200B and 200C, which are situated one below the other in the y-direction. A distance dx between columns of the matrix arrangement that are adjacent in the x-direction is smaller than a distance dy between rows that are adjacent in the y-direction. Expressed differently, a lateral distance between an xMR sensor element 100 and magnetically free layers 216A, 216B laterally adjacent thereto is smaller in the x-direction than in the y-direction.

FIG. 6B schematically shows a sensor arrangement 600B according to a further example implementation.

The sensor arrangement 600B comprises a 2-dimensional matrix arrangement composed of a plurality of xMR sensor elements 100A, 100B and magnetically free layers 216A, 216B that are respectively laterally adjacent thereto in the x-direction. Here, each xMR sensor element 100A, 100B is formed from two xMR sensor elements that are directly adjacent in the x-direction. Magnetically free layers 216A, 216B are arranged adjacent to each of the xMR sensor elements 100A, 100B, 100C on the left and right in the x-direction. FIG. 6B shows a matrix with two rows and four columns by way of example. Each row forms a magnetoresistive sensor 200 having an xMR sensor element 100 that is embedded in the x-direction between adjacent magnetically free layers 216A, 216B. In contrast to the previous example implementations, an xMR sensor element 100 is formed here by two xMR sensor elements that are arranged adjacently in the x-direction. That is to say, two xMR sensor elements arranged adjacently in the x-direction are here embedded between adjacent magnetically free layers 216A, 216B in the x-direction. A first row forms a first (sub) sensor 200A having a first xMR sensor element 100A (formed by two xMR sensor elements arranged adjacently in the x-direction), which is embedded in the x-direction between adjacent magnetically free layers 216A, 216B. A second row forms a second (sub) sensor 200B having a second xMR sensor element 100B (formed by two xMR sensor elements arranged adjacently in the x-direction), which is embedded in the x-direction between adjacent magnetically free layers 216A, 216B. A first column is formed by the two magnetically free layers 216A of the sensors 200A, 200B, which are situated one below the other in the y-direction. Two further columns are formed by the xMR sensor elements 100A, 100B of the sensors 200A, 200B, which are situated one below the other in the y-direction. A fourth column is formed by the two magnetically free layers 216B of the sensors 200A, 200B, which are situated one below the other in the y-direction. A distance dx between adjacent columns in the x-direction is smaller than a distance dy between adjacent rows in the y-direction. Expressed differently, a lateral distance dx between an xMR sensor element 100 and magnetically free layers 216A, 216B laterally adjacent thereto is smaller in the x-direction than in the y-direction. While the xMR sensor elements 100A, 100B are electrically connected (energized) between the top electrode 510 and the bottom electrode 520, the magnetically free layers 216A, 216B acting as shields or magnetic field concentrators are not connected (de-energized). This can also be achieved for example by the corresponding additional wiring.

In summary, example implementations therefore relate to additional vortex disks in the vicinity of an xMR sensor.

The aspects and features described in connection with a particular one of the preceding examples may also be combined with one or more of the further examples in order to replace an identical or similar feature of this further example or to additionally introduce the feature into the further example.

It is also understood that the disclosure of a plurality of steps, processes, operations or functions disclosed in the description or claims shall not be interpreted as being mandatorily in the order described, unless this is explicitly stated in the individual case or is absolutely necessary for technical reasons. Therefore, the preceding description does not limit the performance of a plurality of steps or functions to a specific order. Furthermore, in further examples, an individual step, an individual function, an individual process or an individual operation can include a plurality of substeps, subfunctions, subprocesses or suboperations and/or be subdivided into them.

If some aspects in the preceding sections have been described in association with an apparatus or a system, these aspects should also be understood as a description of the corresponding method. In this case, for example, a block, an apparatus or a functional aspect of the apparatus or of the system can correspond to a feature, for instance a method step, of the corresponding method. Accordingly, aspects described in connection with a method should also be understood as a description of a corresponding block, a corresponding element, a property or a functional feature of a corresponding apparatus or a corresponding system.

The following claims are hereby incorporated in the detailed description, where each claim can be a separate example by itself. It should also be noted that, although a dependent claim in the claims refers to a particular combination with one or more other claims, other examples may also include a combination of the dependent claim with the subject matter of any other dependent or independent claim. Such combinations are hereby expressly proposed, unless it is stated in the individual case that a particular combination is not intended. Furthermore, features of a claim should also be included for any other independent claim, even if this claim is not directly defined as being dependent on this other independent claim.

### ASPECTS

The following provides an overview of some Aspects of the present disclosure:

Aspect 1: A magnetoresistive sensor, comprising: a magnetoresistive sensor element formed from a layer stack, having a magnetically free layer having a magnetically free vortex magnetization, and at least one reference layer having a reference magnetization in a predetermined direction; and adjacent magnetically free layers each having a respective magnetically free vortex magnetization, wherein the adjacent magnetically free layers are arranged along the predetermined direction on opposite sides of the magnetoresistive sensor element and laterally adjacent to the magnetoresistive sensor element.

Aspect 2: The magnetoresistive sensor as recited in Aspect 1, wherein the magnetically free layer of the magnetoresistive sensor element and the adjacent magnetically free layers have identical ratios of thickness to diameter.

Aspect 3: The magnetoresistive sensor as recited in Aspect 2, wherein the magnetically free layer of the magnetoresistive sensor element and the adjacent magnetically free layers have identical geometric dimensions.

Aspect 4: The magnetoresistive sensor as recited in any of Aspects 1-3, wherein a lateral distance between the magnetoresistive sensor element and an adjacent magnetically free layer of the adjacent magnetically free layers is smaller than twice a diameter of the magnetoresistive sensor element or is smaller than twice a diameter of the adjacent magnetically free layer.

Aspect 5: The magnetoresistive sensor as recited in any of Aspects 1-4, wherein the magnetoresistive sensor element is an electrically connected device and the adjacent magnetically free layers are electrically open-circuited devices.

Aspect 6: The magnetoresistive sensor as recited in any of Aspects 1-5, wherein the adjacent magnetically free layers are formed in a same layer of the layer stack as the magnetically free layer of the magnetoresistive sensor element.

Aspect 7: The magnetoresistive sensor as recited in any of Aspects 1-6, wherein the adjacent magnetically free layers are formed in layers other than the magnetically free layer of the magnetoresistive sensor element.

Aspect 8: The magnetoresistive sensor as recited in any of Aspects 1-7, wherein the magnetically free layer of the magnetoresistive sensor element and the adjacent magnetically free layers are each formed in a circular-disk-shaped manner.

Aspect 9: The magnetoresistive sensor as recited in any of Aspects 1-8, further comprising: a two-dimensional matrix arrangement composed of a plurality of magnetoresistive sensor elements and a plurality of sets of adjacent magnetically free layers, wherein each set of the plurality of sets of adjacent magnetically free layers is laterally adjacent to a respective magnetoresistive sensor element of the plurality of magnetoresistive sensor elements, wherein lateral distances between adjacent columns of the two-dimensional matrix arrangement are smaller than lateral distances between adjacent rows of the two-dimensional matrix arrangement, wherein each row extends along a respective predetermined direction of a respective reference magnetization, and wherein each column extends in a respective direction perpendicular to each respective predetermined direction.

Aspect 10: The magnetoresistive sensor as recited in any of Aspects 1-9, wherein the magnetoresistive sensor element is configured as a tunnel magnetoresistive (TMR) sensor element.

Aspect 11: A magnetoresistive sensor, comprising: a two-dimensional matrix arrangement composed of a plurality of magnetoresistive sensor elements and a plurality of additional magnetically free layers arranged laterally adjacent to the plurality of magnetoresistive sensor elements in each case, wherein each magnetoresistive sensor element has a respective magnetically free layer having a respective magnetically free vortex magnetization and a respective reference layer having a respective reference magnetization in a respective predetermined direction, wherein the two-dimensional matrix arrangement has respective pairs of additional magnetically free layers arranged along a respective predetermined direction on opposite sides of each respective magnetoresistive sensor element and laterally adjacent to the respective magnetoresistive sensor element, wherein a lateral distance between an magnetoresistive sensor element and additional magnetically free layers laterally adjacent thereto is smaller in the predetermined direction than in a direction perpendicular to the predetermined direction.

Aspect 12: The magnetoresistive sensor as recited in Aspect 1, wherein the adjacent magnetically free layers include: a first adjacent magnetically free layer arranged on a first lateral side of the magnetoresistive sensor element; and a second adjacent magnetically free layer arranged on a second lateral side of the magnetoresistive sensor element, laterally opposite to the first lateral side.

Aspect 13: The magnetoresistive sensor as recited in Aspect 12, wherein the respective magnetically free vortex magnetization of each adjacent magnetically free layer is configured to align with the magnetically free vortex magnetization of the magnetically free layer of the magnetoresistive sensor element in order to form a linear stray field between the first adjacent magnetically free layer and the second adjacent magnetically free layer.

Aspect 14: The magnetoresistive sensor as recited in Aspect 12, wherein the respective magnetically free vortex magnetization of each adjacent magnetically free layer is configured to align with the magnetically free vortex magnetization of the magnetically free layer of the magnetoresistive sensor element in order to increase a measurement sensitivity of the magnetoresistive sensor element in the predetermined direction.

Aspect 15: The magnetoresistive sensor as recited in Aspect 12, wherein the respective magnetically free vortex magnetization of each adjacent magnetically free layer is configured to align with the magnetically free vortex magnetization of the magnetically free layer of the magnetoresistive sensor element in order to decrease a measurement sensitivity of the magnetoresistive sensor element in a direction perpendicular to the predetermined direction.

Aspect 16: The magnetoresistive sensor as recited in Aspect 12, wherein the respective magnetically free vortex magnetization of each adjacent magnetically free layer is configured to align with the magnetically free vortex magnetization of the magnetically free layer of the magnetoresistive sensor element in order to stabilize an orientation of the at least one reference layer.

Aspect 17: The magnetoresistive sensor as recited in Aspect 9, wherein each set of the plurality of sets of adjacent magnetically free layers includes: a first respective adjacent magnetically free layer arranged on a first lateral side of the respective magnetoresistive sensor element; and a second respective adjacent magnetically free layer arranged on a second lateral side of the respective magnetoresistive sensor element, laterally opposite to the first lateral side.

Aspect 18: A magnetoresistive sensor, comprising: a two-dimensional matrix arrangement composed of a plurality of magnetoresistive sensor elements and a plurality of additional magnetically free layers arranged laterally adjacent to the plurality of magnetoresistive sensor elements in each case, wherein each magnetoresistive sensor element has a respective magnetically free layer having a respective magnetically free vortex magnetization and a respective reference layer having a respective reference magnetization in a respective predetermined direction, wherein each additional magnetically free layer has a respective magnetically free vortex magnetization, wherein two-dimensional matrix arrangement includes a plurality of sub-sensors, including a first sub-sensor formed in a first row of the two-dimensional matrix and a second sub-sensor formed in a second row of the two-dimensional matrix, wherein the first sub-sensor includes a first additional magnetically free layer arranged in a first column of the two-dimensional matrix, a first magnetoresistive sensor element arranged in a second column of the two-dimensional matrix, and a second additional magnetically free layer arranged in a third column of the two-dimensional matrix, the first magnetoresistive sensor element being arranged between the first additional magnetically free layer and the second additional magnetically free layer in a first respective predetermined direction, and wherein the second sub-sensor includes a third additional magnetically free layer arranged in the first column of the two-dimensional matrix, a second magnetoresistive sensor element arranged in the second column of the two-dimensional matrix, and a fourth additional magnetically free layer arranged in the third column of the two-dimensional matrix, the second magnetoresistive sensor element being arranged between the third additional magnetically free layer and the fourth additional magnetically free layer in a second respective predetermined direction.

Aspect 19: The magnetoresistive sensor as recited in Aspect 18, wherein lateral distances between adjacent columns of the two-dimensional matrix arrangement are smaller than lateral distances between adjacent rows of the two-dimensional matrix arrangement, wherein each row extends along a respective predetermined direction of a respective reference magnetization, and wherein each column extends in a respective direction perpendicular to each respective predetermined direction.

Aspect 20: The magnetoresistive sensor as recited in any of Aspects 18-19, wherein the respective magnetically free vortex magnetization of the first additional magnetically free layer and the second additional magnetically free layer are configured to align with the magnetically free vortex magnetization of the magnetically free layer of the first magnetoresistive sensor element in order to increase a measurement sensitivity of the first magnetoresistive sensor element in the first respective predetermined direction, and wherein the respective magnetically free vortex magnetization of the third additional magnetically free layer and the fourth additional magnetically free layer are configured to align with the magnetically free vortex magnetization of the magnetically free layer of the second magnetoresistive sensor element in order to increase a measurement sensitivity of the second magnetoresistive sensor element in the second respective predetermined direction.

Aspect 21: A system configured to perform one or more operations recited in one or more of Aspects 1-20.

Aspect 22: An apparatus comprising means for performing one or more operations recited in one or more of Aspects 1-20.

1. A magnetoresistive sensor, comprising:
a magnetoresistive sensor element formed from a layer stack, having a magnetically free layer having a magnetically free vortex magnetization, and at least one reference layer having a reference magnetization in a predetermined direction; and
adjacent magnetically free layers each having a respective magnetically free vortex magnetization, wherein the adjacent magnetically free layers are arranged along the predetermined direction on opposite sides of the magnetoresistive sensor element and laterally adjacent to the magnetoresistive sensor element.

2. The magnetoresistive sensor as claimed in claim 1, wherein the magnetically free layer of the magnetoresistive sensor element and the adjacent magnetically free layers have identical ratios of thickness to diameter.

3. The magnetoresistive sensor as claimed in claim 2, wherein the magnetically free layer of the magnetoresistive sensor element and the adjacent magnetically free layers have identical geometric dimensions.

4. The magnetoresistive sensor as claimed in claim 1, wherein a lateral distance between the magnetoresistive sensor element and an adjacent magnetically free layer of the adjacent magnetically free layers is smaller than twice a diameter of the magnetoresistive sensor element or is smaller than twice a diameter of the adjacent magnetically free layer.

5. The magnetoresistive sensor as claimed in claim 1, wherein the magnetoresistive sensor element is an electrically connected device and the adjacent magnetically free layers are electrically open-circuited devices.

6. The magnetoresistive sensor as claimed in claim 1, wherein the adjacent magnetically free layers are formed in a same layer of the layer stack as the magnetically free layer of the magnetoresistive sensor element.

7. The magnetoresistive sensor as claimed in claim 1, wherein the adjacent magnetically free layers are formed in layers other than the magnetically free layer of the magnetoresistive sensor element.

8. The magnetoresistive sensor as claimed in claim 1, wherein the magnetically free layer of the magnetoresistive sensor element and the adjacent magnetically free layers are each formed in a circular-disk-shaped manner.

9. The magnetoresistive sensor as claimed in claim 1, further comprising:
a two-dimensional matrix arrangement composed of a plurality of magnetoresistive sensor elements and a plurality of sets of adjacent magnetically free layers, wherein each set of the plurality of sets of adjacent magnetically free layers is laterally adjacent to a respective magnetoresistive sensor element of the plurality of magnetoresistive sensor elements,
wherein lateral distances between adjacent columns of the two-dimensional matrix arrangement are smaller than lateral distances between adjacent rows of the two-dimensional matrix arrangement,
wherein each row extends along a respective predetermined direction of a respective reference magnetization, and
wherein each column extends in a respective direction perpendicular to each respective predetermined direction.

10. The magnetoresistive sensor as claimed in claim 1, wherein the magnetoresistive sensor element is configured as a tunnel magnetoresistive (TMR) sensor element.

11. A magnetoresistive sensor, comprising:
a two-dimensional matrix arrangement composed of a plurality of magnetoresistive sensor elements and a plurality of additional magnetically free layers arranged laterally adjacent to the plurality of magnetoresistive sensor elements in each case,
wherein each magnetoresistive sensor element has a respective magnetically free layer having a respective magnetically free vortex magnetization and a respective reference layer having a respective reference magnetization in a respective predetermined direction,
wherein the two-dimensional matrix arrangement has respective pairs of additional magnetically free layers arranged along a respective predetermined direction on opposite sides of each respective magnetoresistive sensor element and laterally adjacent to the respective magnetoresistive sensor element,
wherein a lateral distance between a magnetoresistive sensor element and additional magnetically free layers laterally adjacent thereto is smaller in the predetermined direction than in a direction perpendicular to the predetermined direction.

12. The magnetoresistive sensor as claimed in claim 1, wherein the adjacent magnetically free layers include:
a first adjacent magnetically free layer arranged on a first lateral side of the magnetoresistive sensor element; and
a second adjacent magnetically free layer arranged on a second lateral side of the magnetoresistive sensor element, laterally opposite to the first lateral side.

13. The magnetoresistive sensor as claimed in claim 12, wherein the respective magnetically free vortex magnetization of each adjacent magnetically free layer is configured to align with the magnetically free vortex magnetization of the magnetically free layer of the magnetoresistive sensor element in order to form a linear stray field between the first adjacent magnetically free layer and the second adjacent magnetically free layer.

14. The magnetoresistive sensor as claimed in claim 12, wherein the respective magnetically free vortex magnetization of each adjacent magnetically free layer is configured to align with the magnetically free vortex magnetization of the magnetically free layer of the magnetoresistive sensor element in order to increase a measurement sensitivity of the magnetoresistive sensor element in the predetermined direction.

15. The magnetoresistive sensor as claimed in claim 12, wherein the respective magnetically free vortex magnetization of each adjacent magnetically free layer is configured to align with the magnetically free vortex magnetization of the magnetically free layer of the magnetoresistive sensor element in order to decrease a measurement sensitivity of the magnetoresistive sensor element in a direction perpendicular to the predetermined direction.

16. The magnetoresistive sensor as claimed in claim 12, wherein the respective magnetically free vortex magnetization of each adjacent magnetically free layer is configured to align with the magnetically free vortex magnetization of the magnetically free layer of the magnetoresistive sensor element in order to stabilize an orientation of the at least one reference layer.

17. The magnetoresistive sensor as claimed in claim 9, wherein each set of the plurality of sets of adjacent magnetically free layers includes:
a first respective adjacent magnetically free layer arranged on a first lateral side of the respective magnetoresistive sensor element; and
a second respective adjacent magnetically free layer arranged on a second lateral side of the respective magnetoresistive sensor element, laterally opposite to the first lateral side.

18. A magnetoresistive sensor, comprising:
a two-dimensional matrix arrangement composed of a plurality of magnetoresistive sensor elements and a plurality of additional magnetically free layers arranged laterally adjacent to the plurality of magnetoresistive sensor elements in each case,
wherein each magnetoresistive sensor element has a respective magnetically free layer having a respective magnetically free vortex magnetization and a respective reference layer having a respective reference magnetization in a respective predetermined direction,
wherein each additional magnetically free layer has a respective magnetically free vortex magnetization,
wherein two-dimensional matrix arrangement includes a plurality of sub-sensors, including a first sub-sensor formed in a first row of the two-dimensional matrix and a second sub-sensor formed in a second row of the two-dimensional matrix,
wherein the first sub-sensor includes a first additional magnetically free layer arranged in a first column of the two-dimensional matrix, a first magnetoresistive sensor element arranged in a second column of the two-dimensional matrix, and a second additional magnetically free layer arranged in a third column of the two-dimensional matrix, the first magnetoresistive sensor element being arranged between the first additional magnetically free layer and the second additional magnetically free layer in a first respective predetermined direction, and
wherein the second sub-sensor includes a third additional magnetically free layer arranged in the first column of the two-dimensional matrix, a second magnetoresistive sensor element arranged in the second column of the two-dimensional matrix, and a fourth additional magnetically free layer arranged in the third column of the two-dimensional matrix, the second magnetoresistive sensor element being arranged between the third additional magnetically free layer and the fourth additional magnetically free layer in a second respective predetermined direction.

19. The magnetoresistive sensor as claimed in claim 18, wherein lateral distances between adjacent columns of the two-dimensional matrix arrangement are smaller than lateral distances between adjacent rows of the two-dimensional matrix arrangement,
wherein each row extends along a respective predetermined direction of a respective reference magnetization, and
wherein each column extends in a respective direction perpendicular to each respective predetermined direction.

20. The magnetoresistive sensor as claimed in claim 18, wherein the respective magnetically free vortex magnetization of the first additional magnetically free layer and the second additional magnetically free layer are configured to align with the magnetically free vortex magnetization of the magnetically free layer of the first magnetoresistive sensor element in order to increase a measurement sensitivity of the first magnetoresistive sensor element in the first respective predetermined direction, and
wherein the respective magnetically free vortex magnetization of the third additional magnetically free layer and the fourth additional magnetically free layer are configured to align with the magnetically free vortex magnetization of the magnetically free layer of the second magnetoresistive sensor element in order to increase a measurement sensitivity of the second magnetoresistive sensor element in the second respective predetermined direction.
